(19) United States
(12) Patent Application Publication
(10) Pub. No.: US 2008/0020727 A1
(43) Pub. Date: Jan. 24, 2008

(54) Circular and Linear Polarization LNB

(75) Inventors: David John Roulston, Mossley (GB); Ronald P.A. Schiltmans, Toenisvorst (DE)

Correspondence Address: BABCOCK IP, PLLC, P.O.BOX 488, 4934 WILDWOOD DRIVE, BRIDGMAN, MI, 49106, US

(73) Assignee: ANDREW CORPORATION, Westchester, IL (US)

(21) Appl. No.: 11/459,032

(22) Filed: Jul. 21, 2006

(51) Int. Cl. H04B 1/10; H05K 3/20

(52) U.S. Cl. 455/303; 29/831

(57) ABSTRACT

An LNB for simultaneous reception of circular and linear polarization radio frequency signals, having a circular waveguide coupled to a waveguide to microstrip turnstile transition. The microstrip outputs coupled to a multi-layer printed circuit board having symmetrical signal paths on separate layers. Each symmetrical signal path including a first combiner coupled to a low noise amplifier that is coupled to a splitter. A first output of each of the splitters having a linear polarization and a second output of each of the splitters coupled to a branch line combiner having two outputs, each of the two outputs having opposite hands of circular polarization.

### BACKGROUND

Satellite communication systems are generally well known in the art. A satellite data signal is concentrated by a reflector dish upon a Low Noise Block (LNB) operative to receive and differentiate between a plurality of different signal polarizations contained within the data signal. To improve data bandwidth, for example in consumer direct to home (DTH) applications it is desirable to provide a single LNB that can simultaneously receive circular and linear polarized signals.

Previous combined circular and linear polarized receive capable LNBs applied two data paths arranged at 90 degrees to each other. Improvements are desired with respect to cross polar discrimination, phase matching and or signal magnitude balancing at the corresponding LNB output(s).

The increasing competition for mass market consumer reflector antennas, for example for DTH satellite communications, has focused attention on improved electrical performance and cost reductions resulting from increased materials, manufacturing and service efficiencies. Further, reductions in required assembly operations and the total number of discrete parts are desired.

Therefore, it is an object of the invention to provide an apparatus that overcomes deficiencies in the prior art.

### BRIEF DESCRIPTION OF THE DRAWINGS

The accompanying drawings, which are incorporated in and constitute a part of this specification, illustrate embodiments of the invention and, together with the general and detailed descriptions of the invention appearing herein, serve to explain the principles of the invention.

FIG. 1 is a schematic angled exploded isometric view of the front side of an LNB according to an exemplary embodiment of the invention.

FIG. 2 is a schematic angled exploded isometric view of the back side of an LNB according to an exemplary embodiment of the invention.

FIG. 3 is a side view of the LNB shown in FIG. 1.

FIG. 4 is a schematic block diagram of an exemplary embodiment of the invention.

FIG. 5 is a schematic view of an RF printed circuit board, side A, according to an exemplary embodiment the invention.

FIG. 6 is a schematic view of an RF printed circuit board, side B, according to an exemplary embodiment the invention.

### DETAILED DESCRIPTION

An exemplary embodiment of an LNB 10 according to the invention has a high cross polar discrimination (XPD) waveguide to microstrip turnstile transition 12 having four microstrip transition 24 output(s) X1, X2, Y1, Y2 feeding into, for example, a multiple layer Printed Circuit Board (PCB) 14 having a symmetrical circuit layout.

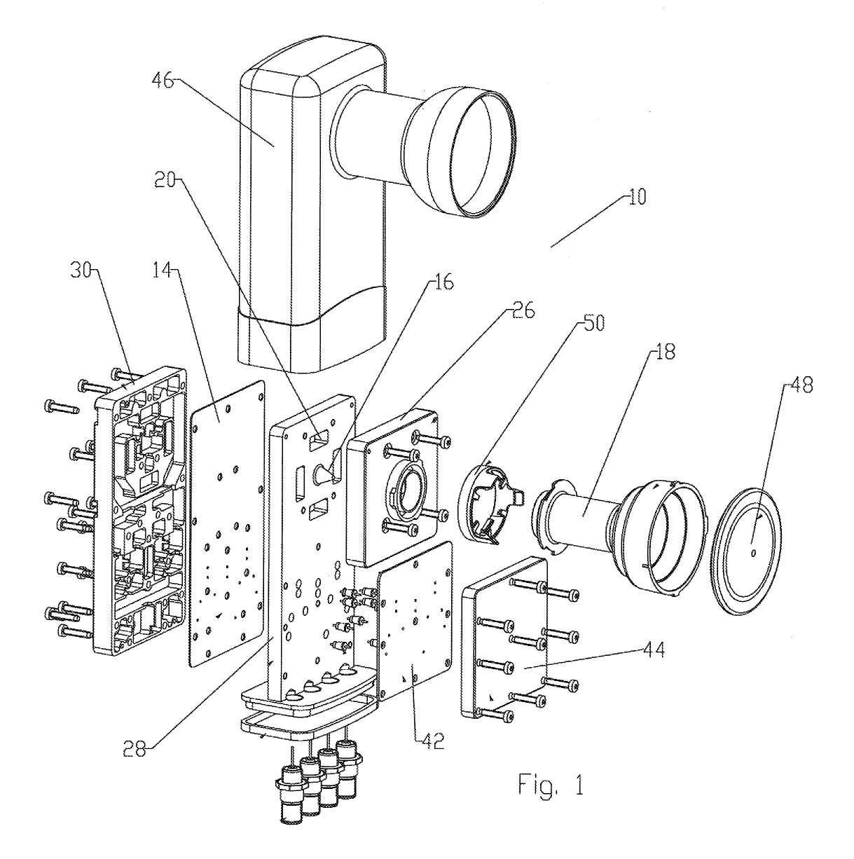

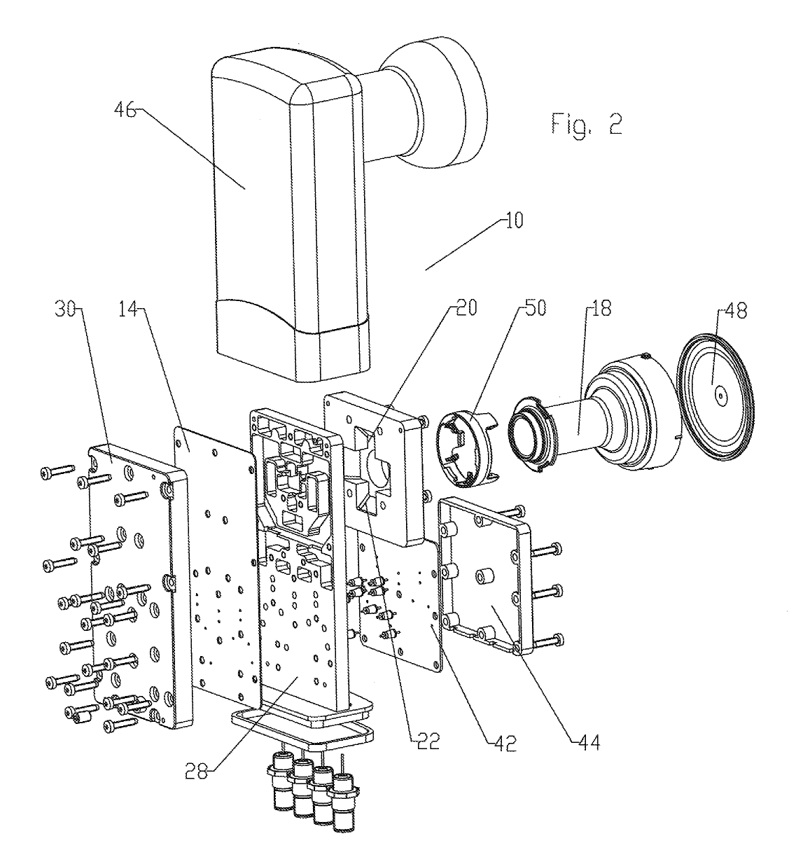

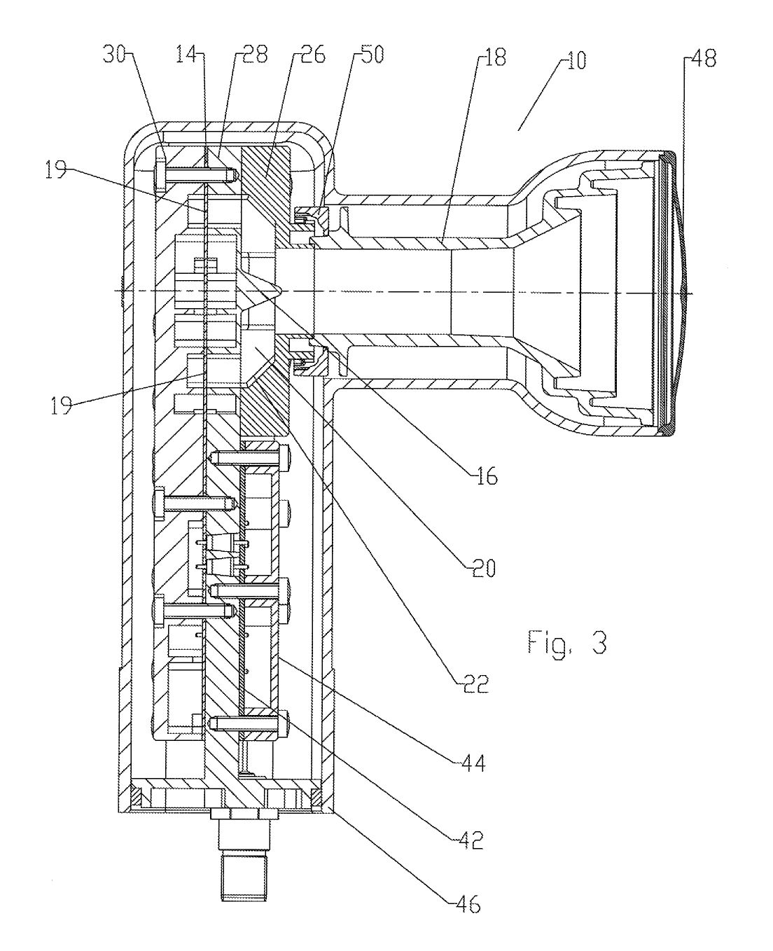

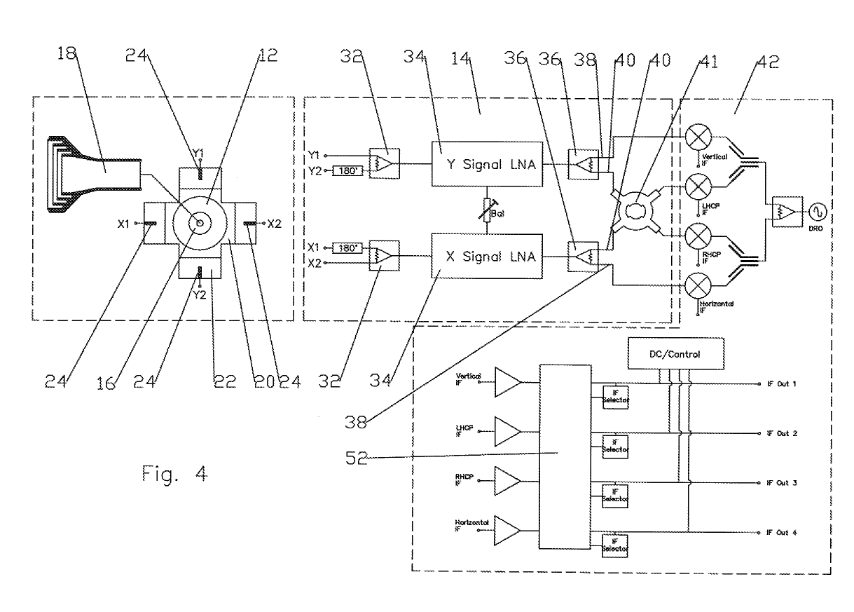

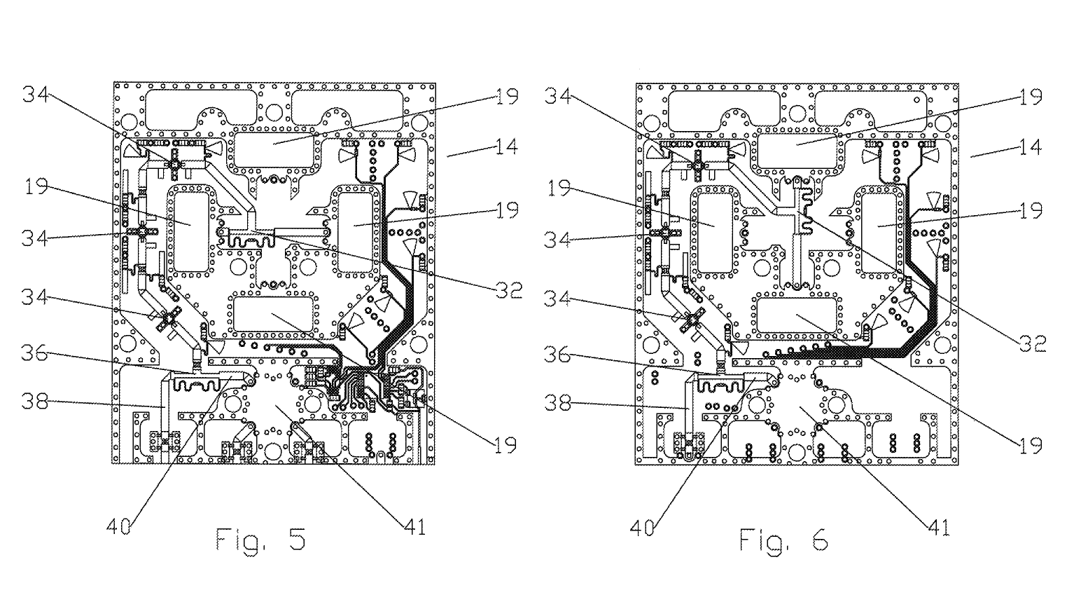

As shown for example in FIGS. 1-4, the XPD waveguide to microstrip turnstile transition 12 has a deflector 16 positioned proximate the center of the feed waveguide 18 end. The feed waveguide 18 may have a range of cross sections, such as circular, oval and rectangular or the like. The deflector 16 redirects signals received into the feed waveguide 18 into four 90 degree rectangular path(s) 20 generally normal to the feed waveguide 18 longitudinal axis, each rectangular path 20 having a reflector surface 22 that redirects the path again generally parallel to the waveguide longitudinal axis. Thereby, radio frequency (RF) signals present in the waveguide are divided into four rectangular path(s) 20, coaxial with the feed waveguide 18 and spatially offset from one another. The rectangular path(s) 20 are arranged in a first parallel pair X1, X2 and a second parallel pair Y1, Y2, the first and second pairs X1, X2 and Y1, Y2, having a width dimension aligned orthogonally to each other. Preferably, the rectangular path(s) 20 each have an equivalent length to minimize phase differences. Microstrip transition(s) 24 are placed in each rectangular path 20 at corresponding dielectric and or physical aperture(s) 19 of the PCB 14 to couple RF signals received into the feed waveguide 18 and further to each rectangular path 20 onto electrical circuits of the PCB 14 for further processing.

The rectangular path(s) 20 may be formed from a transition plate 26 seated upon a base casting 28 that also serves as a PCB 14 support and electrical shield and of which the deflector 16 may be formed an integral part. A RF screen 30 may be applied to the other side of the PCB 14 to terminate the rectangular path(s) 20 a desired distance beyond the microstrip transition(s) 24 and to reduce electrical interference with electrical circuits on the PCB 14.

As shown for example in FIG. 4, on the PCB 14 each microstrip transition 24 parallel pair is combined at a first signal combiner 32 before passage through a Low Noise Amplifier (LNA), for example a three stage LNA 34. The amplified signals are then passed through a second signal combiner, arranged in reverse as a splitter 36, to present a pair of signals at a first output 38 and a second output 40.

One output of each splitter 36 corresponds to a first and second linear polarity, ie vertical and horizontal linear polarization associated with the orthogonal arrangement of the microstrip turnstile transition first and second parallel pair X1, X2 and Y1, Y2 it was originally received in. The other output of each of the splitter 36 is coupled to a branch line combiner 41, for example a four branch 90 degree hybrid stripline combiner, to generate the corresponding first and second circular polarities, ie right hand and left hand circular polarizations. Using a stripline based combiner maintains equal phase paths between the circuits printed on each side of the PCB 14 and the branch line combiner 41. Further circuitry located on the PCB and or an IF/switching PCB 42 performs mixing with a local oscillator such as a dielectric resonator oscillator (DRO) for down-conversion of each polarity of the RF signal to form signal ouputs: Vertical IF, LHCP IF, RHCP IF and Horizontal IF. Further amplification may be applied and a switching capability, for example via a 4×4 IF switching matrix 52 to select any of the four available signal polarities by any of the four outputs IF Out 1-4.

The signal combiners, the splitters and the LNA circuits arrayed between them associated with each microstrip transition 24 parallel pair are preferably arranged on first and second layers of the PCB 14, such as on the side A and Side B of the PCB 14 as shown for example in FIGS. 5 and 6. The circuits may be arranged symmetrically on the first and second layers for optimal phase and magnitude matching between the two signal paths of each parallel pair. The symmetrical arrangement simplifies matching the length of each corresponding trace on each layer of the PCB 14, improving phase and amplitude matching, which then provides maximum cross polar discrimination between the left and right hand circular polarized signals derived from signals from side A and side B, combined by the branch line combiner 41. Further, the LNA 34 circuits of each of side A and side B may be provided with independent bias adjustment capability, allowing the resulting gain of the LNA(s) 34 to be independently adjusted.

Power supply and conditioning circuits may also be include on the PCB 14 or IF/switching PCB 42, interconnected through the base casting via coaxially shielded interconnections to the PCB 14. The IF/switching PCB 42 may also be shielded by an IF screen 44 that sandwiches the IF/switching PCB 42 against the base casting.

One skilled in the art will appreciate that the transition plate 26, base casting 28, RF screen 30 and IF screen 44 may each be configured to enable precision and cost effective manufacture via molding technologies such as die casting or injection molding with a conductive material or surface coating. An LNB assembly according to the invention has a reduced number of discrete components and a compact overall size.

A housing 46 and or a radome 48 may be applied over the LNB assembly to environmentally seal it. Where the feed waveguide 18 is adapted to clip into place upon the transition plate 26 directly or via a retaining ring that is keyed to the base casting supporting the RF PCB, alignment procedures during assembly of the resulting LNB assembly are simplified.

Table of Parts

| | |
|---|---|
| 10 | LNB |
| 12 | microstrip turnstile transition |
| 14 | printed circuit board |
| 16 | deflector |
| 18 | feed waveguide |
| 19 | aperture |
| 20 | rectangular path |
| 22 | reflector surface |
| 24 | microstrip transition |
| 26 | transition plate |
| 28 | base casting |
| 30 | rf screen |
| 32 | first signal combiner |
| 34 | low noise amplifier |
| 36 | splitter |
| 38 | first output |
| 40 | second output |
| 41 | branch line combiner |
| 42 | IF/Switching printed circuit board |
| 44 | IF screen |
| 46 | housing |
| 48 | radome |
| 50 | retaining ring |
| 52 | switching matrix |

Where in the foregoing description reference has been made to ratios, integers, components or modules having known equivalents then such equivalents are herein incorporated as if individually set forth.

While the present invention has been illustrated by the description of the embodiments thereof, and while the embodiments have been described in considerable detail, it is not the intention of the applicant to restrict or in any way limit the scope of the appended claims to such detail. Additional advantages and modifications will readily appear to those skilled in the art. Therefore, the invention in its broader aspects is not limited to the specific details, representative apparatus, methods, and illustrative examples shown and described. Accordingly, departures may be made from such details without departure from the spirit or scope of applicant's general inventive concept. Further, it is to be appreciated that improvements and/or modifications may be made thereto without departing from the scope or spirit of the present invention as defined by the following claims.

What is claimed is:

1. An LNB for circular and linear polarization radio frequency signals, comprising:
a feed waveguide coupled to
a four output microstrip turnstile transition coupled to a first pair and a second pair of microstrip transitions of a multi-layer printed circuit board having symmetrical signal paths on separate layers; each symmetrical signal path including a first signal combiner coupled to a low noise amplifier that is coupled to a splitter with two outputs;
the first output of the first layer corresponding to a first linear polarity and the first output on the second layer corresponding to a second linear polarity;
the second output of the first layer and the second output of the second layer coupled to a branch line combiner; a first output of the branch line combiner is a first circular polarity and a second output of the branch line combiner is a second circular polarity.

2. The LNB of claim 1, wherein the first output of each splitter and the two outputs of each branch line combiner are coupled to a 4×4 IF switching matrix;
the 4×4 IF switching matrix having four outputs, each of the four outputs selectable from any of the first output of each splitter and the first and second outputs of the branch line combiner.

3. The LNB of claim 1, wherein the first pair of microstrip transitions is arranged with a width dimension orthogonal to the width dimension of the second pair of microstrip transitions.

4. The LNB of claim 1, wherein the first combiner, the low noise amplifier and the splitter of the first layer and the second layer are arranged symmetrical to each other.

5. The LNB of claim 1, wherein the low noise amplifier of the first layer and the low noise amplifier of the second layer have independently adjustable bias voltages.

6. The LNB of claim 1, wherein the low noise amplifier of the first layer and the low noise amplifier of the second layer have independently adjustable gain.

7. The LNB of claim 1, wherein the first layer is a front side of the multi-layer printed circuit board and the second layer is a back side of the multi-layer printed circuit board.

8. The LNB of claim 1, wherein the low noise amplifier of the first layer and the second layer is a three stage amplifier.

9. The LNB of claim 1, wherein the four output microstrip turnstile transition has a transition plate with an aperture, four grooves extending radially from the aperture spaced apart by 90 degrees, each of the four grooves ending at a reflector surface; and
a base casting having a deflector and four holes;
the feed waveguide mounted upon the transition plate aligned with the aperture and the transition plate mounted upon the base casting with the deflector projecting into the aperture; the transition plate seated against the base casting forming four rectangular paths along the grooves that change direction at the reflector(s) to pass through the holes;
the printed circuit board coupled to the base casting, the apertures of the printed circuit board aligned with the holes.

10. The LNB of claim 1, wherein the branch line combiner is a stripline combiner.

11. An LNB for simultaneous reception of circular and linear polarization radio frequency signals, comprising:
a feed waveguide; the feed waveguide coupled to
a transition plate with grooves extending from an aperture; the transition plate adjacent a base casting; the grooves in combination with the base casting forming four rectangular paths;
a deflector projecting from the base casting proximate the aperture is positioned to deflect the radio frequency signals received into the feed waveguide into the four rectangular paths;
a reflector in each of the four rectangular paths deflecting the radio frequency signals towards the base casting, coaxial with a longitudinal axis of the waveguide;
the rectangular paths passing through the base casting as a first pair and a second pair, the first pair having a width dimension arranged orthogonal to a width dimension of the second pair; and
a printed circuit board adjacent to the base casting with a microstrip transition projecting into each of the four rectangular paths.

12. The LNB of claim 11, wherein the microstrip transitions from each of the first pair are coupled to a first signal combiner on a first layer of the printed circuit board and the microstrip transitions from each of the second pair are coupled to a first signal combiner on a second layer of the printed circuit board; the first signal combiner of the first layer and the first signal combiner of the second layer coupled to a low noise amplifier of the first layer and the second layer, respectively; the low noise amplifier of the first layer and the low noise amplifier of the second layer coupled to a splitter of the first layer and the second layer, respectively; a first output of the splitter of the first layer having a first linear polarity and a first output of the splitter of the second layer having a second linear polarity;
a second output of the splitter of the first layer and a second output of the splitter of the second layer coupled to a branch line combiner having a first output having a first circular polarity and a second output having a second, opposite hand, circular polarity.

13. The LNB of claim 12, wherein the first output of each splitter and the two outputs of the branch line combiner are coupled to a 4×4 IF switching matrix;
the 4×4 IF switching matrix having four outputs, each of the four outputs selectable from any of the first output of each splitter of the first and second layers and the first and second outputs of the four branch 90 degree stripline combiner.

14. The LNB of claim 13, wherein the 4×4 IF switching matrix is located on an IF/Switching printed circuit board.

15. The LNB of claim 14, wherein the IF/Switching printed circuit board includes downconversion circuitry for the first output of each splitter of the first and second layers and the two outputs of the branch line combiner.

16. The LNB of claim 12, further including an RF shield; the printed circuit board positioned between the RF shield and the base casting.

17. The LNB of claim 16, wherein the RF Shield has cavities aligned with the aperture(s) to terminate the rectangular paths.

18. The LNB of claim 12, wherein the branch line combiner is a stripline combiner.

19. A method of manufacturing an LNB for simultaneous reception of circular and linear polarization radio frequency signals, comprising the steps of:
forming a feed waveguide;
molding a transition plate with grooves extending from an aperture;
molding a base casting;
mounting the transition plate adjacent to the base casting; the grooves in combination with the base casting forming four rectangular paths;
a deflector formed in the base casting projecting proximate the aperture is positioned to deflect the radio frequency signals received into the feed waveguide into the four rectangular paths;
a reflector formed in each of the four rectangular paths deflecting the radio frequency signals towards the base casting, coaxial with a longitudinal axis of the waveguide; the rectangular paths passing through the base casting arranged as a first pair and a second pair, the first pair having a width dimension arranged orthogonal to a width dimension of the second pair;
positioning a printed circuit board adjacent to the base casting with a microstrip transition projecting into each of the four rectangular paths; and
coupling an end of the feed waveguide to the transition plate coaxial with the aperture.
